(19) United States
(12) Patent Application Publication
(10) Pub. No.: US 2026/0260854 A1
(43) Pub. Date: Sep. 3, 2026

(54) PLASMA PROCESSING APPARATUS

(71) Applicant: Tokyo Electron Limited, Tokyo (JP)

(72) Inventor: Takaaki KATO, Nirasaki City (JP)

(21) Appl. No.: 19/652,258

(22) Filed: Apr. 20, 2026

Related U.S. Application Data
(63) Continuation of application No. PCT/JP2024/037243, filed on Oct. 18, 2024.

(30) Foreign Application Priority Data
Nov. 1, 2023 (JP) 2023-187494

(51) Int. Cl. H01J 37/32

(52) U.S. Cl. CPC H01J 37/32651; H01J 37/3211; H01J 37/32165; H01J 37/32834

(57) ABSTRACT

The plasma processing apparatus includes a chamber configured to provide a processing space, a substrate support provided in the processing space, an introducer configured to introduce electromagnetic waves into a plasma generation space, and a choke provided along an outer periphery of the processing space, wherein the choke includes a dielectric disposed such that a portion of the dielectric is exposed to the processing space, a first portion having a slit in which the dielectric is embedded, a second portion having a space that is provided outward of the first portion with respect to the processing space and extends from the slit, and a plurality of coils disposed in the space of the second portion and configured such that an angle of each of the plurality of coils with respect to a direction of magnetic flux in the space of the second portion is changeable.

### CROSS-REFERENCE TO RELATED APPLICATION

The application is a Bypass Continuation Application of PCT International Application No. PCT/JP2024/037243, filed on October 18, 2024 and designating the United States, the international application being based upon and claiming the benefit of priority from Japanese Patent Application No. 2023-187494, filed on November 1, 2023, the entire contents of which are incorporated herein by reference.

### TECHNICAL FIELD

Exemplary embodiments of the present disclosure relate to a plasma processing apparatus.

### BACKGROUND

A plasma processing apparatus is used for plasma-processing a substrate. One type of plasma processing apparatus generates plasma by using electromagnetic waves introduced into a plasma generation space. Further, in some cases, the plasma processing apparatus includes a choke to suppress propagation of the electromagnetic waves to an unnecessary portion. Such a plasma processing apparatus is disclosed in Patent Document 1 below.

### Prior Art Document

### Patent Document

Patent Document 1: Japanese Patent Laid-Open Publication No. 2023-010536

### SUMMARY

In one exemplary embodiment, a plasma processing apparatus is provided. The plasma processing apparatus includes a chamber, a substrate support, an introducer, and a choke. The chamber provides a processing space. The substrate support is provided in the processing space. The introducer is configured to introduce electromagnetic waves into a plasma generation space. The plasma generation space is provided in an upper region in the processing space or above the processing space. The choke is provided along an outer periphery of the processing space and suppresses propagation of the electromagnetic waves to below the plasma generation space. The choke includes a dielectric, a first portion, a second portion, and a plurality of coils. The dielectric is disposed such that a portion of the dielectric is exposed to the processing space. The first portion has a slit in which the dielectric is embedded. The second portion has a space that is provided outward of the first portion with respect to the processing space and extends from the slit. The plurality of coils is disposed in the space of the second portion. An angle of each of the plurality of coils with respect to a direction of magnetic flux in the space of the second portion is changeable.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a plasma processing apparatus according to one exemplary embodiment.

FIG. 2 is a view illustrating a plurality of coils in the plasma processing apparatus according to one exemplary embodiment.

FIG. 3 is a view illustrating an example of a drive applicable to the plasma processing apparatus according to one exemplary embodiment.

FIG. 4 is a view illustrating another example of the drive applicable to the plasma processing apparatus according to one exemplary embodiment.

FIGS. 5A, 5B, and 5C are views illustrating coils applicable as each of a plurality of coils in the plasma processing apparatus according to one exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in details with reference to the accompanying drawings. In addition, in each drawing, same or corresponding portions will be denoted by same reference numerals.

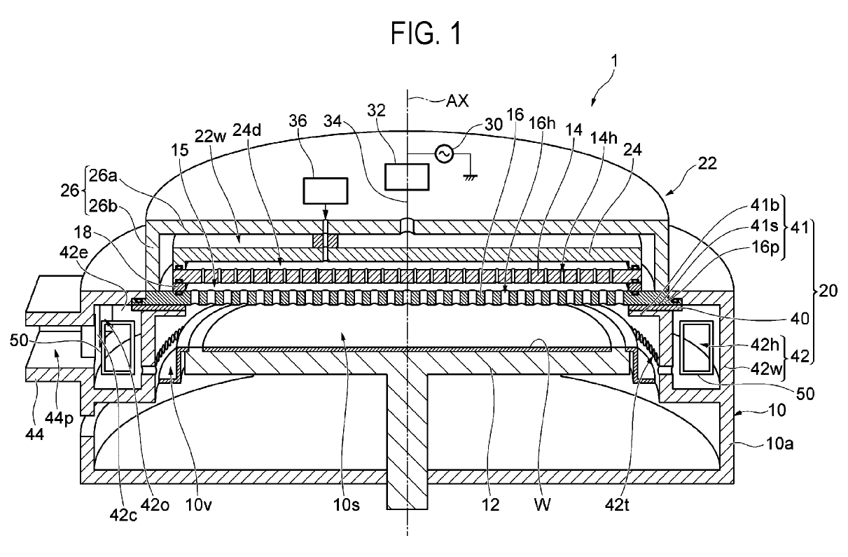

FIG. 1 is a diagram illustrating a plasma processing apparatus according to one exemplary embodiment. A plasma processing apparatus 1 shown in FIG. 1 includes a chamber 10, a substrate support 12, an introducer 18, and a choke 20. The plasma processing apparatus 1 may further include a first electrode 14 and a second electrode 16.

The chamber 10 provides a processing space 10s therein. In the plasma processing apparatus 1, a substrate W is processed in the processing space 10s. The chamber 10 is made of a metal such as aluminum and is grounded. The chamber 10 has a sidewall 10a and is open at an upper end thereof. The chamber 10 and the sidewall 10a may have a substantially cylindrical shape. The processing space 10s is provided inward of the sidewall 10a. A central axis of each of the chamber 10, the sidewall 10a, and the processing space 10s is an axis AX. The chamber 10 may have a corrosion-resistant film on a surface thereof. The corrosion-resistant film may be an yttrium oxide film, an yttrium oxide fluoride film, an yttrium fluoride film, a ceramic film including yttrium oxide or yttrium fluoride, or the like.

The substrate support 12 is provided in the processing space 10s. The substrate support 12 is configured to substantially horizontally support the substrate W placed on an upper surface of the substrate support 12. The substrate support 12 has a substantially disk-like shape. A central axis of the substrate support 12 is the axis AX.

The first electrode 14 is provided above the processing space 10s. The first electrode 14 is made of a conductor such as aluminum and has a substantially disk-like shape. A central axis of the first electrode 14 is the axis AX. The first electrode 14 may have a plurality of gas holes 14h for introducing a gas into a plasma generation space 15 described later. The plurality of gas holes 14h extends in a thickness direction (a vertical direction) of the first electrode 14 and penetrates the first electrode 14.

The second electrode 16 is provided above the substrate support 12 and below the first electrode 14. The second electrode 16 may extend substantially parallel to the first electrode 14. The second electrode 16 is made of a conductor such as aluminum and has a substantially disk-like shape. A central axis of the second electrode 16 is the axis AX. The second electrode 16 closes the upper end opening of the chamber 10 together with a dielectric 40 described later. That is, the second electrode 16 defines the processing space 10s from above.

The first electrode 14 and the second electrode 16 provide the plasma generation space 15 therebetween. That is, in the plasma processing apparatus 1, the plasma generation space 15 is disposed above the processing space 10s. In the plasma generation space 15, plasma is generated from a gas by electromagnetic waves. The second electrode 16 has a plurality of through-holes 16h that guide active species from the plasma in the plasma generation space 15 to the processing space 10s. The plurality of through-holes 16h extends in a thickness direction (a vertical direction) of the second electrode 16 and penetrates the second electrode 16. A cross-sectional area of the plurality of through-holes 16h is set to be relatively large to suppress the active species from being deactivated when the active species pass through the plurality of through-holes 16h. Further, in each of the first electrode 14 and the second electrode 16, a film or plate made of a dielectric material may be provided on a surface facing the plasma generation space 15 to define the plasma generation space 15.

The introducer 18 is configured to introduce electromagnetic waves into the plasma generation space 15 to generate plasma in the plasma generation space 15. The introducer 18 is made of a dielectric material such as quartz, aluminum nitride, or aluminum oxide. The introducer 18 may have a ring shape, and a central axis thereof may be the axis AX. The introducer 18 may be held between a peripheral portion of the first electrode 14 and a peripheral portion 16p of the second electrode 16. The electromagnetic waves introduced from the introducer 18 into the plasma generation space 15 may be radio-frequency waves such as very high frequency (VHF) waves or ultra-high frequency (UHF) waves. The electromagnetic waves are generated by a radio-frequency power supply which will be described later. The electromagnetic waves propagate to the introducer 18 via a waveguide 22 and are introduced from the introducer 18 into the plasma generation space 15.

The waveguide 22 provides a waveguide path 22w. In one embodiment, the waveguide 22 may include the first electrode 14, the second electrode 16, an upper electrode 24, and an upper wall 26. The upper electrode 24 is provided above the first electrode 14. The upper electrode 24 is made of a conductor such as aluminum and has a substantially disk-like shape. A central axis of the upper electrode 24 is the axis AX.

The upper electrode 24 provides a gas diffusion space 24d between the first electrode 14 and the upper electrode 24. A gas supplier 36 is connected to the gas diffusion space 24d. A gas output from the gas supplier 36 is supplied to the plasma generation space 15 via the gas diffusion space 24d and the plurality of gas holes 14h.

The upper wall 26 is made of a conductor such as aluminum. The upper wall 26 is provided to cover the first electrode 14, the second electrode 16, and the upper electrode 24 and forms the waveguide path 22w. The upper wall 26 may include an upper portion 26a and a side portion 26b.

The upper portion 26a has a substantially disk-like shape, and a central axis thereof is the axis AX. The upper portion 26a extends above the upper electrode 24 and in parallel with an upper surface of the upper electrode 24. The side portion 26b has a substantially cylindrical shape, and a central axis thereof is the axis AX. The side portion 26b extends downward from a periphery of the upper portion 26a to surround the first electrode 14, the introducer 18, and the upper electrode 24. A lower end of the side portion 26b is in contact with an upper surface of the peripheral portion 16p of the second electrode 16.

The waveguide path 22w is formed between the upper portion 26a and the upper surface of the upper electrode 24, between the side portion 26b and an outer peripheral surface of the upper electrode 24, between the side portion 26b and an outer peripheral surface of the first electrode 14, and between the side portion 26b and an outer peripheral surface of the introducer 18.

The plasma processing apparatus 1 may further include a radio-frequency power supply 30. The plasma processing apparatus 1 may further include a matcher 32. The radio-frequency power supply 30 is configured to generate radio-frequency power. Electromagnetic waves introduced into the chamber 10 are generated based on the radio-frequency power generated by the radio-frequency power supply 30. The radio-frequency power supply 30 is a power supply capable of changing a frequency of the electromagnetic waves introduced into the chamber 10. The radio-frequency power supply 30 is connected to the upper electrode 24 via the matcher 32 and an electrical line 34. The matcher 32 includes a matching circuit for matching a load impedance of the radio-frequency power supply 30 to an output impedance of the radio-frequency power supply 30. The electrical line 34 extends downward from the matcher 32 and is connected to a center of the upper surface of the upper electrode 24. The electrical line 34 may extend along the axis AX.

The choke 20 is provided along an outer periphery of the processing space 10s to suppress propagation of the electromagnetic waves downward from the plasma generation space 15. In the plasma processing apparatus 1, the choke 20 is configured to suppress emission of the electromagnetic waves from the plasma generation space 15 into the processing space 10s via the plurality of through-holes 16h. The choke 20 includes the dielectric 40, a first portion 41, and a second portion 42. The choke 20 further includes a plurality of coils 50.

The dielectric 40 is made of a dielectric material such as aluminum oxide, aluminum nitride, yttrium oxide, quartz glass, tetrafluoroethylene, or the like. The dielectric 40 is disposed along the outer periphery of the processing space 10s such that a portion thereof (for example, an inner edge thereof) is exposed to the processing space 10s. The dielectric 40 may be a plate-shaped member or may have a ring shape. The dielectric 40 may be disposed such that a central axis thereof coincides with the axis AX.

The dielectric 40 is in contact with a lower surface of the peripheral portion 16p of the second electrode 16. The choke 20 and the dielectric 40 protrude inward of the chamber 10 relative to the sidewall 10a. The choke 20 and the dielectric 40 extend to a vicinity of outermost through-holes 16h among the plurality of through-holes 16h. A shortest distance between the outermost through-holes 16h among the plurality of through-holes 16h and the dielectric 40 is zero or more, and may be 1/10 or less of a wavelength of surface waves (electromagnetic waves) in a lower surface of the second electrode 16.

The first portion 41 forms a slit 41s. The slit 41s may have an annular shape extending around the axis AX. The first portion 41 includes a first conductor 41b and the peripheral portion 16p of the second electrode 16. The first conductor 41b is made of a conductor such as aluminum. The first conductor 41b is disposed below the peripheral portion 16p of the second electrode 16 and extends inward of the chamber 10 from the sidewall 10a of the chamber 10. The first conductor 41b may have a plate shape or a ring shape. The first conductor 41b has a same potential as the chamber 10 and is grounded. The first conductor 41b may be provided integrally with the sidewall 10a of the chamber 10.

The slit 41s is formed between the first conductor 41b and the peripheral portion 16p of the second electrode 16. The dielectric 40 is embedded in the slit 41s. In other words, the dielectric 40 is held between the first conductor 41b and the peripheral portion 16p of the second electrode 16. A position of an inner end of the first conductor 41b in a direction orthogonal to the axis AX may be same as or substantially same as a position of an inner end of the dielectric 40 in the same direction.

The second portion 42 is provided outside the processing space 10s. The second portion 42 may be provided by the sidewall 10a of the chamber 10. The second portion 42 includes a second conductor 42w. The second conductor 42w is made of a conductor such as aluminum. The second conductor 42w provides a space 42h therein. The space 42h is provided outward of the first portion 41 with respect to the processing space 10s and extends from the slit 41s. The space 42h is continuous with an outer end of the dielectric 40. The space 42h may be an annular space extending in a circumferential direction with respect to the axis AX.

The dielectric 40 and the space 42h are designed to increase an impedance of the choke 20 with respect to electromagnetic waves. That is, the dielectric 40 and the space 42h are designed such that parallel resonance of the electromagnetic waves is generated in the choke 20. Further, as described above, the choke 20 and the dielectric 40 extend to the vicinity of the outermost through-holes 16h among the plurality of through-holes 16h. With the choke 20 configured as described above, even when the electromagnetic waves are emitted from the plurality of through-holes 16h, the electromagnetic waves immediately return toward the second electrode 16 without propagating along the sidewall 10a. Therefore, emission of the electromagnetic waves from the plasma generation space 15 into the processing space 10s is suppressed.

In the plasma processing apparatus 1, the first conductor 41b is bent upward, that is, toward the dielectric 40 relative to the first conductor 41b, due to temperature rising caused by heat input from plasma. Therefore, high adhesion between each of the first conductor 41b and the peripheral portion 16p of the second electrode 16 and the dielectric 40 is ensured. Therefore, generation of a gap between each of the first conductor 41b and the peripheral portion 16p of the second electrode 16 and the dielectric 40 is suppressed.

The dielectric 40 and the first conductor 41b extend along the peripheral portion 16p of the second electrode 16. Therefore, disturbance of a gas flow in the processing space 10s by the dielectric 40 and the first conductor 41b is suppressed. In addition, the choke 20 can have a sufficient capacitance component to function as a choke.

In one embodiment, the second conductor 42w may be an exhaust duct that provides the space 42h. In this case, the second conductor 42w provides the space 42h as an exhaust path for exhausting a gas in the processing space 10s therethrough. An exhaust path 10v is provided between the second conductor 42w and the substrate support 12. The first conductor 41b extends above the exhaust path 10v. The second conductor 42w has a plurality of holes 42t that connects the exhaust path 10v and the space 42h to each other. The plurality of holes 42t may be formed in the second conductor 42w, that is, in an inner peripheral wall of the exhaust duct, or may be arranged along a circumferential direction.

An outer peripheral wall 42e of the second conductor 42w (i.e., the exhaust duct) has an opening 42o. Another exhaust duct 44 is connected to the second conductor 42w (i.e., the exhaust duct). The exhaust duct 44 provides an exhaust path 44p. The exhaust duct 44 and the exhaust path 44p extend in a direction away from the chamber 10, for example, in a radial direction with respect to the axis AX. The exhaust path 44p is connected to the space 42h via the opening 42o. Further, an exhaust device is connected to the exhaust duct 44. The exhaust device may include a vacuum pump such as a dry pump and/or a turbomolecular pump, and an automatic pressure control valve.

A short-circuit 42c is provided in the opening 42o. The short-circuit 42c is made of a conductor such as aluminum and has, for example, a rod shape. The short-circuit 42c electrically connects a pair of edge portions (i.e., an upper edge portion and a lower edge portion) defining the opening 42o to each other. The short-circuit 42c divides the opening 42o into a plurality of portions. A length of each of the plurality of portions of the opening 42o along a circumferential direction may be set to be 1/10 or less of a wavelength of the electromagnetic waves in the space 42h of the second conductor 42w. By the short-circuit 42c, the outer peripheral wall 42e functions as a short-circuiting surface with respect to the electromagnetic waves even in a portion in which the opening 42o is provided.

As shown in FIG. 1, the outer end of the dielectric 40 may protrude into the space 42h. Further, as shown in FIG. 1, the space 42h may extend downward from an upper surface of the dielectric 40. That is, a position of an upper end of the space 42h in the vertical direction may be same as or substantially same as a position of the upper surface of the dielectric 40 in the vertical direction. In addition, in another example, the space 42h may extend upward from a lower surface of the dielectric 40. That is, a position of a lower end of the space 42h in the vertical direction may be same as or substantially same as a position of the lower surface of the dielectric 40 in the vertical direction.

In the plasma processing apparatus 1 described above, the outer end of the dielectric 40 protrudes into the space 42h. Therefore, discharge in the space 42h is suppressed. Further, the outer end of the dielectric 40 extends at an upper end portion (or a lower end portion) of the space 42h. Therefore, in the space 42h, disturbance of a gas flow is suppressed by the dielectric 40.

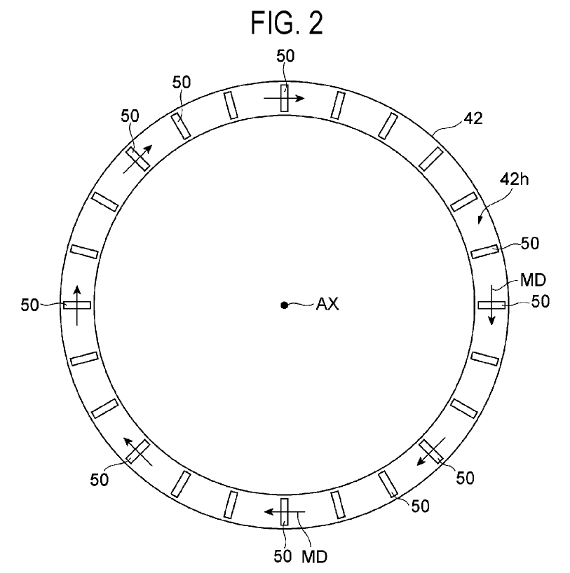

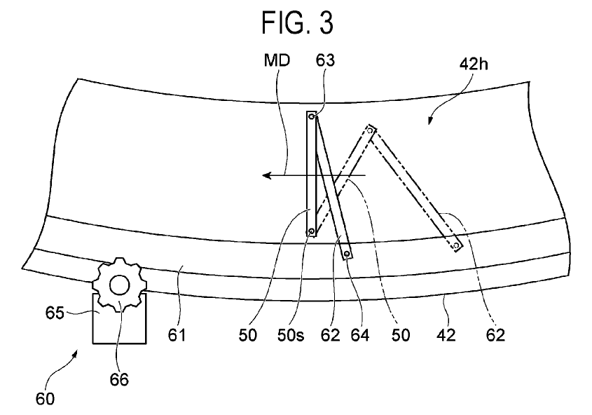

Hereinafter, reference is made to FIGS. 2 and 3 together with FIG. 1. FIG. 2 is a view illustrating a plurality of coils in the plasma processing apparatus according to one exemplary embodiment. FIG. 3 is a view illustrating an example of a drive applicable to the plasma processing apparatus according to one exemplary embodiment.

The plurality of coils 50 is arranged in the space 42h. The plurality of coils 50 may be arranged along the circumferential direction with respect to the axis AX in the space 42h. Further, the plurality of coils 50 may be arranged at equal intervals in the space 42h. Each of the plurality of coils 50 may extend along a plane. That is, a winding of each of the plurality of coils 50 may extend along the plane. A potential of each of the plurality of coils 50 is a floating potential.

Each of the plurality of coils 50 is configured to be capable of changing an angle thereof with respect to a magnetic flux direction MD in the space 42h. In one embodiment, the magnetic flux direction MD in the space 42h is a tangential direction with respect to the axis AX. Each of the plurality of coils 50 is configured to be rotatable about a central axis of a rotation shaft 50s (see FIG. 3) that rotatably supports the coil 50, that is, about a rotation axis. The rotation axis is located in the plane along which the corresponding coil 50 extends and in a vertical plane including the axis AX. In the example of FIG. 3, the rotation axis is parallel to the axis AX. In the example of FIG. 3, the coil 50 has a pair of edge portions extending in the vertical direction. The coil 50 is pivotally supported by the rotation shaft 50s at one of the pair of edge portions. The rotation axis of the coil 50 may extend in any direction as long as the rotation axis is located in the vertical plane including the axis AX. Further, the rotation axis of the coil 50 may extend in any direction as long as the angle of the coil 50 with respect to the magnetic flux direction MD is changeable.

The plasma processing apparatus 1 may further include a drive 60 configured to change the angle of each of the plurality of coils 50. In one embodiment, the drive 60 may be configured to interlock movements of the plurality of coils 50, as shown in FIG. 3.

In the example shown in FIG. 3, the drive 60 includes a ring 61 and a plurality of links 62. The ring 61 is disposed in the space 42h and is configured to be rotatable about a central axis thereof, that is, the axis AX.

The plurality of links 62 is disposed in the space 42h. The plurality of links 62 is connected to the plurality of coils 50, respectively, and is also connected to the ring 61. Specifically, one end portion of the link 62 corresponding to the other one of the pair of edge portions of each of the plurality of coils 50 is pivotally supported by a shaft 63. The shaft 63 extends in the vertical direction. Further, the other end portion of each of the plurality of links 62 is pivotally supported by a shaft 64 fixed to the ring 61. The shaft 64 extends in the vertical direction.

According to the drive 60 shown in FIG. 3, each of the plurality of coils 50 rotates about the rotation axis thereof (the central axis of the corresponding rotation shaft 50s) by rotating the ring 61 about the axis AX. Thus, using the drive 60, it is possible to change the angle of each of the plurality of coils 50 by interlocking movements of the plurality of coils 50. In addition, the ring 61 may be rotated manually by an operator. Alternatively, as shown in FIG. 3, the ring 61 may be rotated by an actuator 65 such as a motor. In this case, a gear 66 coupled to a drive shaft extending from the actuator 65 may be engaged with the ring 61. In this case, the gear 66 is rotated by the actuator 65, and the ring 61 rotates according to the rotation of the gear 66.

In the choke 20 of the plasma processing apparatus 1, the space 42h functions as an inductor such as a coil. The plasma processing apparatus 1 can adjust the angle of each of the plurality of coils 50 with respect to the magnetic flux direction MD in the space 42h. That is, the plasma processing apparatus 1 can adjust a mutual inductance of each of the plurality of coils 50 in the space 42h. Therefore, the plasma processing apparatus 1 can adjust a parallel resonance frequency of the choke 20. For example, the plasma processing apparatus 1 may adjust the angle of each of the plurality of coils 50 to adjust the parallel resonance frequency of the choke 20 according to a frequency of the electromagnetic waves. Alternatively, the plasma processing apparatus 1 may adjust the angle of each of the plurality of coils 50 to reduce or eliminate an error in the parallel resonance frequency of the choke 20 with respect to a design value.

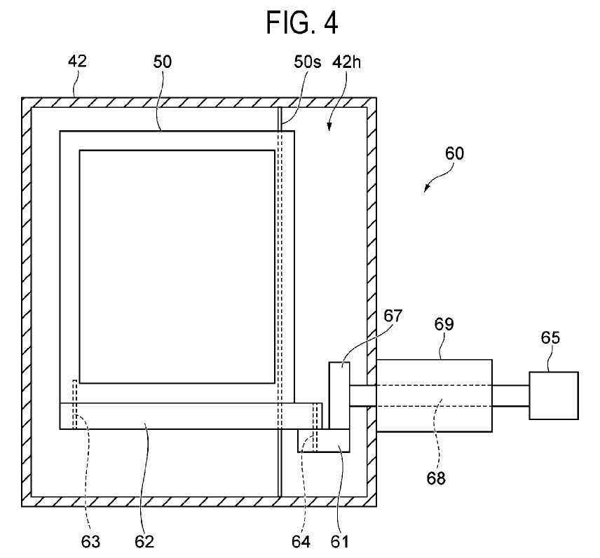

Hereinafter, another example of the drive will be described with reference to FIG. 4. FIG. 4 is a view illustrating another example of the drive applicable to the plasma processing apparatus according to one exemplary embodiment. FIG. 4 shows a configuration of the drive in the vertical plane including the axis AX. The plasma processing apparatus 1 may include the drive 60 shown in FIG. 4 in place of the drive 60 shown in FIG. 3.

As shown in FIG. 4, the drive 60 may further include a drive shaft 68 for rotationally driving the ring 61. The drive shaft 68 extends from the space 42h to an outside of the space 42h. The drive shaft 68 may extend in the radial direction with respect to the axis AX. The drive shaft 68 may extend through a seal 69. The seal 69 seals the exhaust duct at an outer side of the second conductor 42w, which is the exhaust duct. The seal 69 is, for example, a bellows-type rotary feedthrough.

According to the drive 60 shown in FIG. 4, it is possible to introduce the drive shaft 68 coupled to the actuator 65 from the outside of the exhaust duct into the space 42h while maintaining airtightness of the exhaust duct by the seal 69. The drive shaft 68 is coupled to a gear 67engaged with the ring 61. According to the drive 60, the ring 61 is rotated via the gear 67 coupled to the drive shaft 68 as the drive shaft 68 is rotated by the actuator 65. Therefore, the movements of the plurality of coils 50 are interlocked so that the angle of each of the plurality of coils 50 is adjusted.

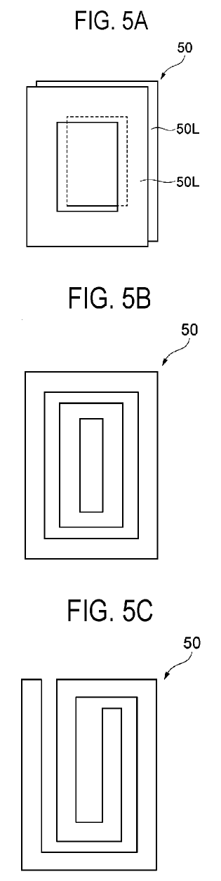

Hereinafter, examples of coils applicable as each of the plurality of coils 50 will be described with reference to FIGS. 5A, 5B, and 5C. FIGS. 5A, 5B, and 5C are views illustrating coils applicable as each of the plurality of coils in the plasma processing apparatus according to one exemplary embodiment.

The winding for each of the plurality of coils 50 may have a rectangular shape and a closed shape, as shown in FIG. 1, FIG. 4, and FIGS. 5A and 5B. Alternatively, as shown in FIG. 5C, the winding of each of the plurality of coils 50 may have a spiral shape. Further, as shown in FIG. 5A, each of the plurality of coils 50 may be constituted by a plurality of layers 50L, each layer including a winding. In addition, as shown in FIG. 5B, each of the plurality of coils 50 may be constituted by a plurality of windings disposed coaxially.

Hereinafter, a substrate processing method according to one exemplary embodiment that can be performed by using the plasma processing apparatus 1 will be described. The substrate processing method includes performing a first plasma process and performing a second plasma process. In each of the first plasma process and the second plasma process, a substrate on the substrate support 12 is processed by plasma generated in the chamber 10. The second plasma process may be performed after the first plasma process. An angle of each of the plurality of coils 50 with respect to the direction MD during a period in which the first plasma process is performed may be different from an angle of each of the plurality of coils 50 with respect to the direction MD during a period in which the second plasma process is performed.

The substrate processing method including the first plasma process and the second plasma process may be a film formation process by atomic layer deposition. The first plasma process may be a plasma process for a precursor deposited on the substrate, and may oxidize or nitride the precursor. The second plasma process may be a plasma process for a film formed by the first plasma process, and may be a plasma process for surface modification of the film.

While various exemplary embodiments have been described above, the present disclosure is not limited to the above-described exemplary embodiments, and various additions, omissions, substitutions, and modifications may be made. In addition, elements in different embodiments can be combined to form other embodiments.

For example, the plasma processing apparatus 1 may not include the second electrode 16. In this case, the plasma generation space 15 is an upper region in the processing space 10s and is located above the substrate support 12.

Further, the drive 60 may include a plurality of actuators for individually changing the angle of each of the plurality of coils 50. Alternatively, the drive 60 may interlock movements of the plurality of coils 50 by a wire, a belt, or the like.

Here, various exemplary embodiments included in the present disclosure are described in [E1] to [E14] below.

[E1]

A plasma processing apparatus, including:

a chamber configured to provide a processing space;

a substrate support provided in the processing space;

an introducer configured to introduce electromagnetic waves into a plasma generation space provided in an upper region in the processing space or above the processing space; and

a choke provided along an outer periphery of the processing space and configured to suppress propagation of the electromagnetic waves to below the plasma generation space,

wherein the choke includes:

a dielectric disposed such that a portion of the dielectric is exposed to the processing space;

a first portion having a slit in which the dielectric is embedded;

a second portion having a space that is provided outward of the first portion with respect to the process space and extends from the slit; and

a plurality of coils disposed in the space of the second portion, and configured such that an angle of each of the plurality of coils with respect to a direction of magnetic flux in the space of the second portion is changeable.

[E2]

The plasma processing apparatus of [E1], wherein the chamber includes an exhaust duct having an exhaust path via which a gas in the processing space is exhausted, and

wherein the space of the second portion is the exhaust path of the exhaust duct.

[E3]

The plasma processing apparatus of [E1] or [E2], wherein the space of the second portion is an annular space extending in a circumferential direction with respect to a central axis of the chamber, and

wherein the plurality of coils is arranged at equal intervals along the circumferential direction in the space of the second portion.

[E4]

The plasma processing apparatus of [E3], wherein the direction of the magnetic flux is a tangential direction.

[E5]

The plasma processing apparatus of any one of [E1] to [E4], wherein each of the plurality of coils extends along a plane and is configured to be rotatable about a rotation axis in the plane.

[E6]

The plasma processing apparatus of any one of [E1] to [E5], further including a drive configured to change the angle of each of the plurality of coils.

[E7]

The plasma processing apparatus of [E1], further including a drive configured to change the angle of each of the plurality of coils,

wherein the space of the second portion is an annular space extending in a circumferential direction with respect to a central axis of the chamber,

wherein the plurality of coils is arranged along the circumferential direction in the space of the second portion,

wherein each of the plurality of coils extends along a plane and is configured to be rotatable about a rotation axis in the plane, and

wherein the drive includes:

a ring disposed in the space of the second portion and configured to be rotatable about a central axis of the ring;

a plurality of links disposed in the space of the second portion, each of the links being connected to a corresponding one of the plurality of coils and to the ring; and

a drive shaft configured to rotationally drive the ring, and extending from the space of the second portion to an outside of the space of the second portion.

[E8]

The plasma processing apparatus of [E7], wherein the chamber includes an exhaust duct having an exhaust path via which a gas in the processing space is exhausted, and

wherein the space of the second portion is the exhaust path of the exhaust duct.

[E9]

The plasma processing apparatus of [E8], wherein the drive shaft extends through a seal provided outside the exhaust duct and configured to seal the exhaust duct.

[E10]

The plasma processing apparatus of [E9], wherein the drive shaft and the seal constitute a bellows-type rotary feedthrough.

[E11]

The plasma processing apparatus of [E10], further including an actuator configured to rotate the drive shaft.

[E12]

The plasma processing apparatus of any one of [E1] to [E11], wherein each of the plurality of coils is constituted by a plurality of layers, each of which includes a winding.

[E13]

The plasma processing apparatus of any one of [E1] to [E12], wherein a potential of each of the plurality of coils is a floating potential.

[E14]

The plasma processing apparatus of any one of [E1] to [E13], further including a radio-frequency power supply configured to generate the electromagnetic waves,

wherein the radio-frequency power supply is configured to change a frequency of the electromagnetic waves.

According to the present disclosure, it is possible to change a resonance frequency of a choke of a plasma processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a chamber configured to provide a processing space;
a substrate support provided in the processing space;
an introducer configured to introduce electromagnetic waves into a plasma generation space provided in an upper region in the processing space or above the processing space; and
a choke provided along an outer periphery of the processing space and configured to suppress propagation of the electromagnetic waves to below the plasma generation space,
wherein the choke includes:
a dielectric disposed such that a portion of the dielectric is exposed to the processing space;
a first portion having a slit in which the dielectric is embedded;
a second portion having a space that is provided outward of the first portion with respect to the processing space and extends from the slit; and
a plurality of coils disposed in the space of the second portion, and configured such that an angle of each of the plurality of coils with respect to a direction of magnetic flux in the space of the second portion is changeable.

2. The plasma processing apparatus of claim 1, wherein the chamber includes an exhaust duct having an exhaust path via which a gas in the processing space is exhausted, and
wherein the space of the second portion is the exhaust path of the exhaust duct.

3. The plasma processing apparatus of claim 1, wherein the space of the second portion is an annular space extending in a circumferential direction with respect to a central axis of the chamber, and
wherein the plurality of coils is arranged at equal intervals along the circumferential direction in the space of the second portion.

4. The plasma processing apparatus of claim 3, wherein the direction of the magnetic flux is a tangential direction.

5. The plasma processing apparatus of claim 1, wherein each of the plurality of coils extends along a plane and is configured to be rotatable about a rotation axis in the plane.

6. The plasma processing apparatus of claim 1, further comprising a drive configured to change the angle of each of the plurality of coils.

7. The plasma processing apparatus of claim 1, further comprising a drive configured to change the angle of each of the plurality of coils,
wherein the space of the second portion is an annular space extending in a circumferential direction with respect to a central axis of the chamber,
wherein the plurality of coils is arranged along the circumferential direction in the space of the second portion,
wherein each of the plurality of coils extends along a plane and is configured to be rotatable about a rotation axis in the plane, and
wherein the drive includes:
a ring disposed in the space of the second portion and configured to be rotatable about a central axis of the ring;
a plurality of links disposed in the space of the second portion, each of the links being connected to a corresponding one of the plurality of coils and to the ring; and
a drive shaft configured to rotationally drive the ring, and extending from the space of the second portion to an outside of the space of the second portion.

8. The plasma processing apparatus of claim 7, wherein the chamber includes an exhaust duct having an exhaust path via which a gas in the processing space is exhausted, and
wherein the space of the second portion is the exhaust path of the exhaust duct.

9. The plasma processing apparatus of claim 8, wherein the drive shaft extends through a seal provided outside the exhaust duct and configured to seal the exhaust duct.

10. The plasma processing apparatus of claim 9, wherein the drive shaft and the seal constitute a bellows-type rotary feedthrough.

11. The plasma processing apparatus of claim 10, further comprising an actuator configured to rotate the drive shaft.

12. The plasma processing apparatus of claim 11, wherein each of the plurality of coils is constituted by a plurality of layers, each of which includes a winding.

13. The plasma processing apparatus of claim 12, wherein a potential of each of the plurality of coils is a floating potential.

14. The plasma processing apparatus of claim 13, further comprising a radio-frequency power supply configured to generate the electromagnetic waves,
wherein the radio-frequency power supply is configured to change a frequency of the electromagnetic waves.

15. The plasma processing apparatus of claim 1, wherein each of the plurality of coils is constituted by a plurality of layers, each of which includes a winding.

16. The plasma processing apparatus of claim 1, wherein a potential of each of the plurality of coils is a floating potential.

17. The plasma processing apparatus of claim 1, further comprising a radio-frequency power supply configured to generate the electromagnetic waves,
wherein the radio-frequency power supply is configured to change a frequency of the electromagnetic waves.
